(19) United States
(12) Patent Application Publication
(10) Pub. No.: US 2015/0303545 A1
(43) Pub. Date: Oct. 22, 2015

(54) NON-RECIPROCAL CIRCUIT ELEMENT

(71) Applicant: Murata Manufacturing Co., Ltd., Nagaokakyo-shi (JP)

(72) Inventor: Daisuke OKUBO, Nagaokakyo-shi (JP)

(21) Appl. No.: 14/754,870

(22) Filed: Jun. 30, 2015

Related U.S. Application Data
(63) Continuation of application No. PCT/JP2014/050416, filed on Jan. 14, 2014.

(30) Foreign Application Priority Data
Jan. 18, 2013 (JP) 2013-007518

(51) Int. Cl. H01P 1/36; H03H 7/38

(52) U.S. Cl. CPC H01P 1/36; H03H 7/38

(57) ABSTRACT

A non-reciprocal circuit element includes a ferrite to which a direct current magnetic field is applied by permanent magnets, and first and second central electrodes arranged on the ferrite so as to cross each other while being insulated from each other. One end of the first central electrode is connected to an input port and another end thereof is connected to an output port. One end of the second central electrode is connected to the output port and another end thereof is connected to ground. A first capacitor is connected between the input port and the output port and a second capacitor is connected between the output port and ground. A resistor is connected between the input port and the output port and a third capacitor and an inductor are connected in series with the resistor R. A fourth capacitor is connected between the input port and ground. Capacitances of the first capacitor and the third capacitor are variable.

### BACKGROUND OF THE INVENTION

1. Field of the Invention

The present invention relates to non-reciprocal circuit elements and in particular relates to non-reciprocal circuit elements such as isolators and circulators preferably for use in microwave bands.

2. Description of the Related Art

In the related art, non-reciprocal circuit elements such as isolators and circulators have a characteristic that they transmit a signal only in a specific predetermined direction and do not transmit a signal in the opposite direction. For example, isolators employ this characteristic when used in a transmission circuit section of a mobile communication apparatus such as a cellular phone.

As an example of such a non-reciprocal circuit element, a non-reciprocal circuit element is described in Japanese Unexamined Patent Application Publication No. 2008-85981 that includes a variable reactance matching mechanism that is connected to another end of each of three central conductors provided on a ferrite. Here, the variable reactance matching mechanism is composed of three capacitors and two switches and can allow the reactance to be changed in four ways and the operational frequency band to be changed in four ways by switching the switches on and off.

However, in the non-reciprocal circuit element, although it is possible to switch between four values with certainty, there is large variation in the coupling capacitance when all three of the capacitors are switched on and optimization is difficult. In addition, loss due to insertion of the variable matching mechanism cannot be ignored.

Furthermore, as described in International Publication No. 2012/20613, a two-port isolator is known in which an isolation frequency can be shifted by making the capacitance of a capacitor provided in parallel with a first central electrode variable. Moreover, as described in Japanese Patent No. 4155342, it is known that isolation is achieved over a wide band by providing an LC series resonance circuit at a terminal resistor.

### SUMMARY OF THE INVENTION

Preferred embodiments of the present invention provide a non-reciprocal circuit element that obtains excellent isolation characteristics across a wide band and that is capable of adjusting an isolation frequency.

A non-reciprocal circuit element according to a preferred embodiment of the present invention includes a permanent magnet, a ferrite to which a direct current magnetic field is applied by the permanent magnet, and a first central electrode and a second central electrode that are arranged on the ferrite so as to cross each other while being insulated from each other, one end of the first central electrode being connected to an input port and another end of the first central electrode being connected to an output port, one end of the second central electrode being connected to the output port and another end of the second central electrode being connected to ground, a first capacitor being connected between the input port and the output port, a second capacitor being connected between the output port and ground, a resistor being connected between the input port and the output port and a third capacitor and an inductor being connected in series with the resistor, a fourth capacitor being connected between the input port and ground, and capacitances of the first capacitor and the third capacitor being variable.

In a non-reciprocal circuit element according to a preferred embodiment of the present invention, by switching capacitances of the first capacitor and the third capacitor, excellent isolation characteristics are obtained across a wide band and an isolation frequency is adjusted while maintaining these isolation characteristics. That is, since it is possible to widen the frequency band, optimization is achieved in many frequency bands by performing switching between capacitances a small number of times.

Furthermore, in a non-reciprocal circuit element according to a preferred embodiment of the present invention, a capacitance of at least either of the second capacitor and the fourth capacitor may be variable. Thus, it is possible to adjust the input/output impedance, and in addition to it being possible to adjust the isolation frequency while maintaining isolation characteristics across a wide band, insertion loss is significantly reduced.

According to various preferred embodiments of the present invention, excellent isolation characteristics are obtained across a wide band and it is possible to adjust an isolation frequency.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A and FIG. 1B are equivalent circuit diagrams illustrating a first basic mode and a second basic mode of a non-reciprocal circuit element.

FIG. 2 is a perspective view illustrating a ferrite-magnet assembly.

FIG. 3 is an equivalent circuit diagram illustrating a non-reciprocal circuit element according to a first preferred embodiment of the present invention.

FIGS. 4A and 4B are graphs illustrating characteristics in the first preferred embodiment of the present invention.

FIGS. 5A and 5B are Smith charts illustrating characteristics in the first preferred embodiment of the present invention.

FIG. 6 is an equivalent circuit diagram illustrating a non-reciprocal circuit element according to a second preferred embodiment of the present invention.

FIGS. 7A and 7B are graphs illustrating characteristics in the second preferred embodiment of the present invention.

FIGS. 8A and 8B are Smith charts illustrating characteristics in the second preferred embodiment of the present invention.

### DETAILED DESCRIPTION OF THE PREFERRED EMBODIMENTS

Hereafter, preferred embodiments of a non-reciprocal circuit element according to the present invention will be described while referring to the accompanying drawings. In each of the drawings, like components and portions are denoted by the same symbols and repeated description thereof is avoided.

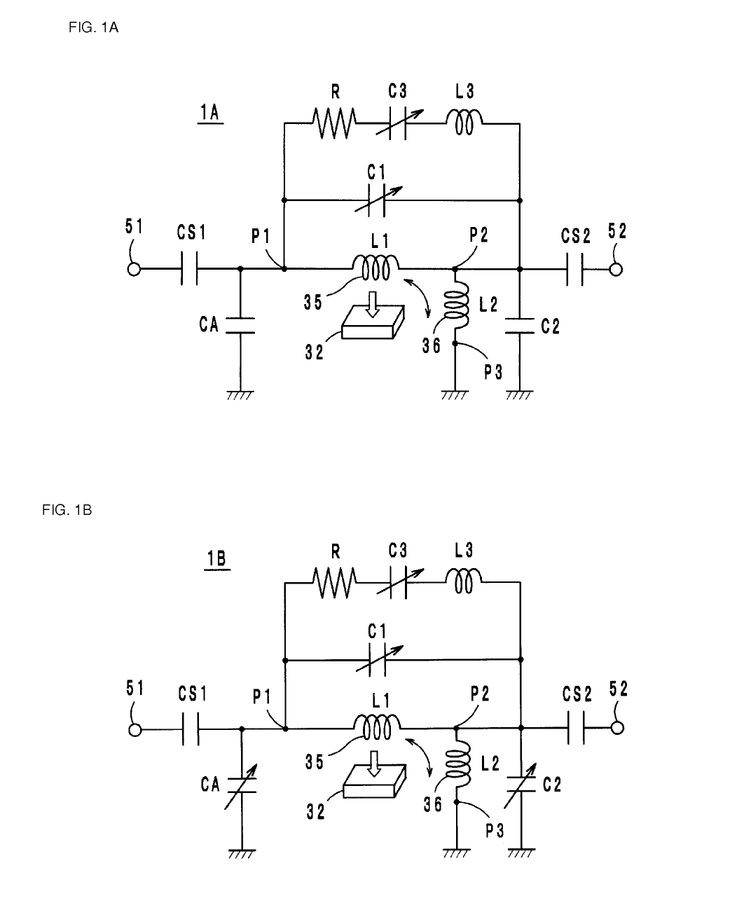

A first basic mode is illustrated in FIG. 1A and a second basic mode is illustrated in FIG. 1B. A non-reciprocal circuit element of a first basic mode (two-port isolator 1A) is a lumped-constant isolator in which a first central electrode 35, which defines an inductor L1, and a second central electrode 36, which defines an inductor L2, are arranged on a ferrite 32 so as to cross each other while being insulated from each other.

One end (port P1) of the first central electrode 35 is connected to an input terminal 51 via a matching capacitor CS1. The other end (port P2) of the first central electrode 35 and one end (port P2) of the second central electrode 36 are connected to an output terminal 52 via a matching capacitor CS2 and the other end (port P3) of the second central electrode 36 is connected to ground.

A matching capacitor C1 is connected in parallel with the first central electrode 35 between the port P1 and the port P2 and a matching capacitor C2 is connected in parallel with the second central electrode 36 between the port P2 and ground. A resistor R and an LC series resonance circuit (including inductor L3 and capacitor C3) are connected in parallel with the first central electrode 35 between the port P1 and the port P2. In addition, an impedance-adjusting capacitor CA connected to ground is connected to the one end of the first central electrode 35.

In the two-port isolator 1A having the above-described circuit configuration, when a high-frequency current is input to the port P1 from the terminal 51, a large high-frequency current flows in the second central electrode 36, a high-frequency current substantially does not flow in the first central electrode 35, insertion loss is small and wide band operation is performed. At the time of operation, since a high-frequency current also substantially does not flow in the resistor R and the LC series resonance circuit (inductor L3 and capacitor C3), it is possible to ignore loss due the LC series resonance circuit and the insertion loss does not increase. In addition, since the capacitor C3 and the inductor L3 are connected in series with the resistor R inserted between the port P1 and the port P2, excellent isolation characteristics are obtained across a wide band.

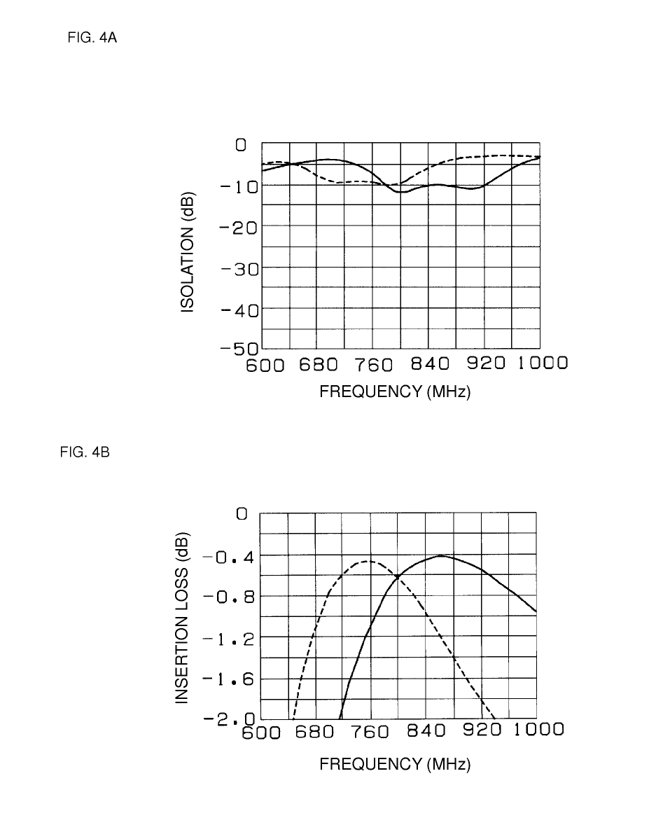

On the other hand, when a high-frequency current is input to the port P2 from the terminal 52, matching is performed over a wide band due to the impedance characteristics of the resistor R and the LC series resonance circuit and the isolation characteristics are improved. Such isolation and insertion loss characteristics will be described while referring to FIGS. 4A, 4B, 5A, 5B, 7A, 7B, 8A, and 8B below.

Furthermore, the capacitor C1 and the capacitor C3 of the isolator 1A preferably are variable-capacitance capacitors. Since the capacitances of the capacitors C1 and C3 can be varied, excellent isolation characteristics are obtained across a wide band and the isolation frequency is able to be adjusted (shifted) while maintaining these isolation characteristics. That is, since it is possible to widen the frequency band, optimization is achieved in many frequency bands by performing switching between capacitances a small number of times. For example, for Bands 5, 8, 13 and 12, the frequency is able to be shifted for any two bands together and the bands are able to be handled by switching between two values (Bands 5 and 8 and Bands 13 and 12).

As illustrated in FIG. 1B, a non-reciprocal circuit element of a second basic mode (two-port isolator 1B) preferably has the same configuration as the two-port isolator 1A of the first basic mode, and in addition the capacitors CA and C2 preferably are variable-capacitance capacitors. In the two-port isolator 1B, the input impedance and the output impedance are adjusted by appropriately changing the capacitances of the capacitors CA and C2. It is sufficient that at least either of the capacitors CA and C2 be a variable-capacitance capacitor.

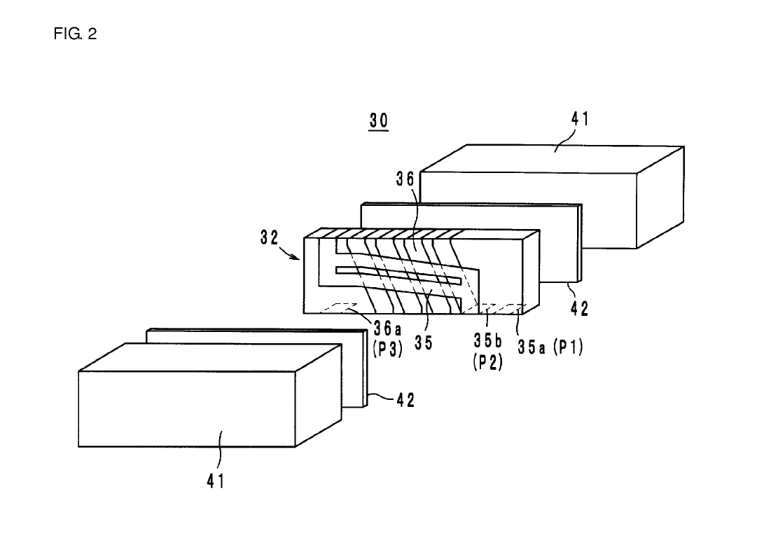

Here, the configuration of principle portions of the two-port isolators 1A and 1B will be described while referring to FIG. 2. The lumped-constant two-port isolators 1A and 1B each include a ferrite-magnet assembly 30 in which permanent magnets are respectively adhered to front and back surfaces of a ferrite 32 via adhesive 42. The first central electrode 35 is wound around the front and back surfaces of the ferrite 32 for one turn, and a one-end electrode 35a defines the port P1 and an other-end electrode 35b defines the port P2. The second central electrode 36 is wound around the front and back surfaces of the ferrite 32 for four turns so as to cross the first central electrode 35 at a certain angle while maintaining an insulated state therewith. The number of turns is arbitrary. One end of the second central electrode 36 is common to the electrode 35b (port P2) and an other-end electrode 36b thereof forms the port P3. In FIG. 2, illustration of the electrodes on the back surface side of the ferrite 32 has been omitted to avoid making the figure too complex.

### First Preferred Embodiment

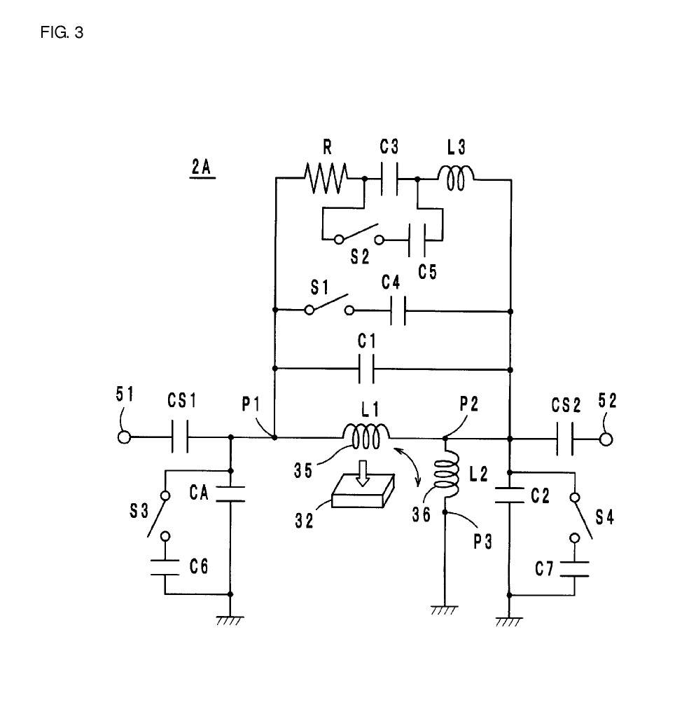

In a non-reciprocal circuit element according to a first preferred embodiment of the present invention (two-port isolator 2A), as illustrated in FIG. 3, a capacitor C4 is connected in parallel with a capacitor C1 and a switching element S1 is provided to switch the capacitor C4 on and off. In addition, a capacitor C5 is connected in parallel with a capacitor C3 and a switching element S2 is provided to switch the capacitor C5 on and off. Furthermore, capacitors C6 and C7 are respectively connected in parallel with capacitors CA and C2 and switching elements S3 and S4 are provided to switch the capacitors C6 and C7 on and off.

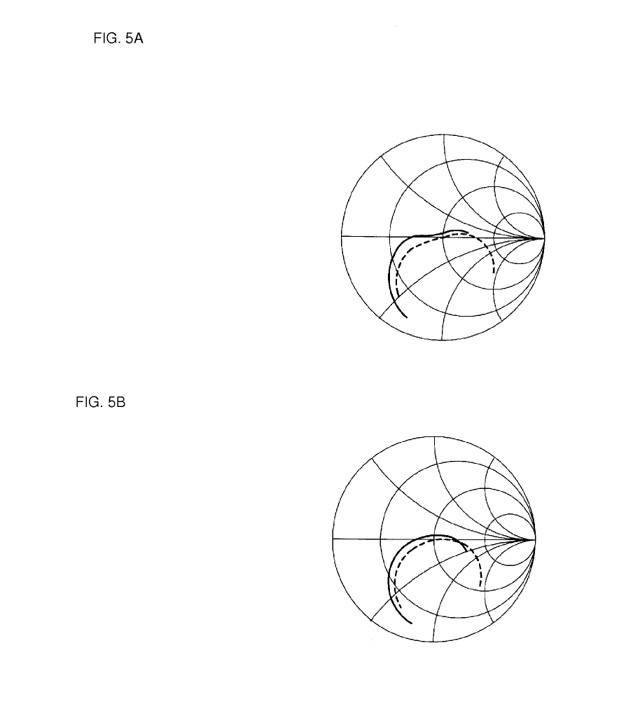

Operation of the two-port isolator 2A is basically the same as that of the first and second basic modes and characteristics thereof are illustrated in FIGS. 4A and 4B. FIG. 4A illustrates isolation characteristics and FIG. 4B illustrates insertion loss characteristics. Impedance characteristics are illustrated in FIGS. 5A and 5B, with FIG. 5A illustrating input impedance (input matching characteristics) and FIG. 5B illustrating output impedance (output matching characteristics). In FIGS. 4A and 4B and FIGS. 5A and 5B, solid lines represent characteristics at a time when the switching elements S1 to S4 have been switched off and dotted lines represent characteristics at a time when the switching elements S1 to S4 have been switched on. That is, in the first preferred embodiment, Bands 5 and 8 and Bands 13 and 12 are handled by simultaneously switching the switching elements S1 to S4 on or off. These characteristics are simulation data obtained with the following specifications.

Capacitor C1: 13.1 pF

Capacitor C4: 4.9 pF

Capacitor C2: 1.1 pF

Capacitor C7: 1.3 pF

Capacitor C3: 0.5 pF

Capacitor C5: 0.3 pF

Capacitor CA: 0.2 pF

Capacitor C6: 0.4 pF

Inductor L3: 54 nH

Resistor R: 70 Ω

### Second Preferred Embodiment

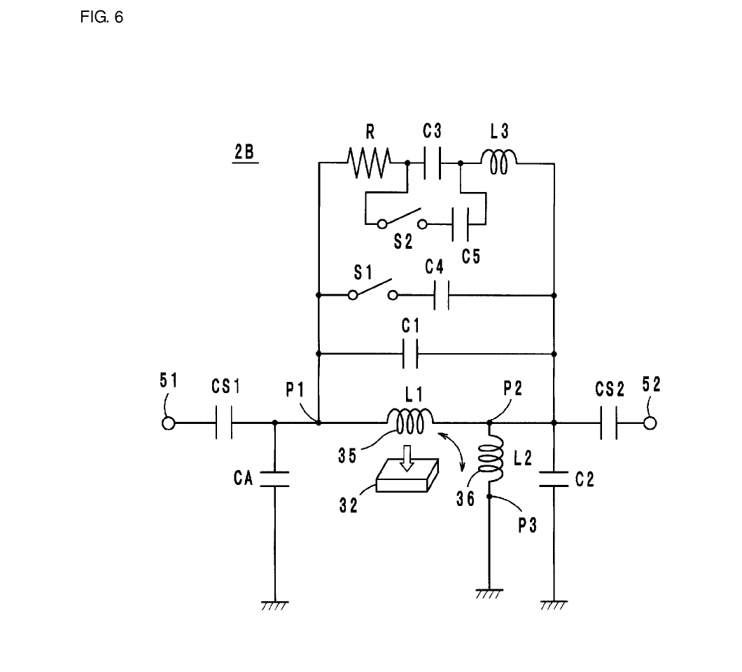

A non-reciprocal circuit element according to a second preferred embodiment of the present invention (two-port isolator 2B), as illustrated in FIG. 6, preferably has the same configuration as the two-port isolator 2A of the first preferred embodiment except that the capacitances of the capacitors CA and C2 are fixed and the operation thereof is also the same.

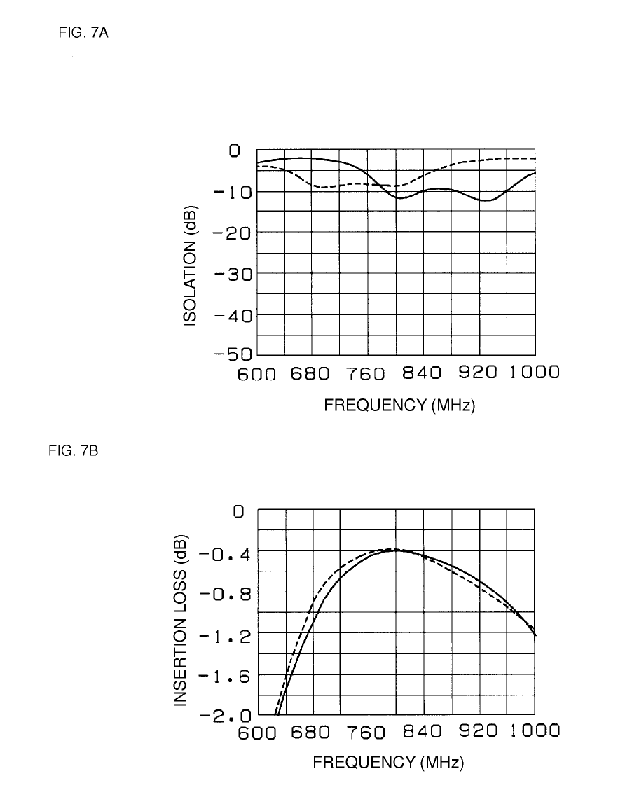

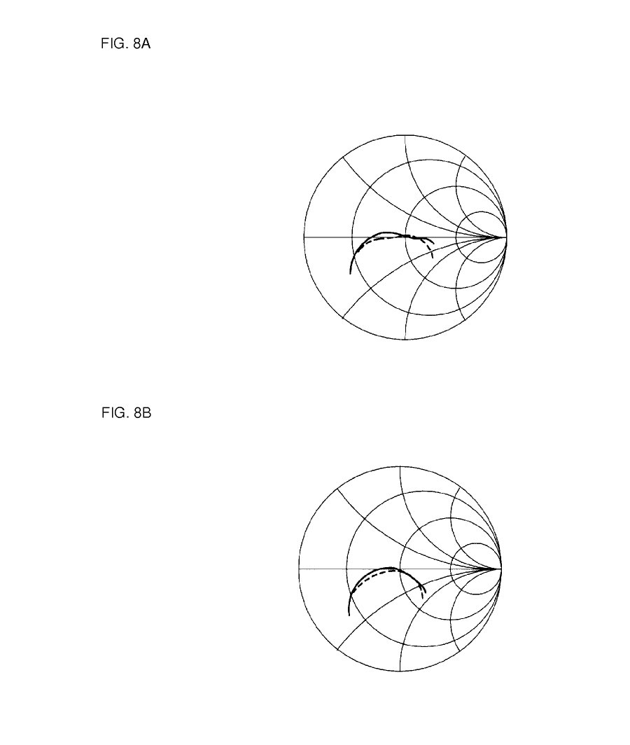

Characteristics of the two-port isolator 2B are illustrated in FIGS. 7A and 7B. FIG. 7A illustrates isolation characteristics and FIG. 7B illustrates insertion loss characteristics. Impedance characteristics are illustrated in FIGS. 8A and 8B, with FIG. 8A illustrating input impedance (input matching characteristics) and FIG. 8B illustrating output impedance (output matching characteristics). In FIGS. 7A and 7B and FIGS. 8A and 8B, solid lines represent characteristics at a time when the switching elements S1 and S2 have been switched on and dotted lines represent characteristics at a time when the switching elements S1 and S2 have been switched off. That is, in the second preferred embodiment, Bands 5 and 8 and Bands 13 and are handled by simultaneously switching the switching elements S1 and S2 on or off. These characteristics are simulation data obtained with the following specifications.

Capacitor C1: 13.1 pF

Capacitor C4: 5 pF

Capacitor C2: 4.9 pF

Capacitor C3: 0.5 pF

Capacitor C5: 0.35 pF

Capacitor CA: 0.4 pF

Inductor L3: 54 nH

Resistor R: 70 Ω

### Other Preferred Embodiments

A non-reciprocal circuit element according to the present invention is not limited to the above-described preferred embodiments and can be modified in various ways within the scope of the gist of the present invention.

For example, the input port P1 and the output port P2 are interchanged if the N poles and the S poles of the permanent magnets 41 are reversed. In addition, the configuration of the ferrite-magnet assembly 30, particularly the shape of the first and second central electrodes 35 and 36 and so forth, is arbitrary.

As described above, preferred embodiments of the present invention are useful in non-reciprocal circuit elements and are particularly excellent in that excellent isolation characteristics are obtained across a wide band and adjustment of the isolation frequency is possible.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. (canceled)

2. A non-reciprocal circuit element comprising:
a permanent magnet;
a ferrite to which a direct current magnetic field is applied by the permanent magnet; and
a first central electrode and a second central electrode that are arranged on the ferrite so as to cross each other while being insulated from each other; wherein
one end of the first central electrode is connected to an input port and another end of the first central electrode is connected to an output port;
one end of the second central electrode is connected to the output port and another end of the second central electrode is connected to ground;
a first capacitor is connected between the input port and the output port;
a second capacitor is connected between the output port and ground;
a resistor is connected between the input port and the output port and a third capacitor and an inductor are connected in series with the resistor;
a fourth capacitor is connected between the input port and ground; and
capacitances of the first capacitor and the third capacitor are variable.

3. The non-reciprocal circuit element according to claim 2, wherein a capacitance of at least either of the second capacitor and the fourth capacitor is variable.

4. The non-reciprocal circuit element according to claim 3, wherein the at least either of the second capacitor and the fourth capacitor includes a plurality of capacitors and operation of the plurality of capacitors is switched by a switching element.

5. The non-reciprocal circuit element according to claim 2, wherein each of the first capacitor and the third capacitor includes a plurality of capacitors and operation of the plurality of capacitors is switched by a switching element.

6. The non-reciprocal circuit element according to claim 2, wherein a first matching capacitor is connected in parallel with the first central electrode between the input port and the output port and a second matching capacitor is connected in parallel with the second central electrode between the output port and ground.

7. The non-reciprocal circuit element according to claim 2, wherein a resistor and an LC series resonance circuit are connected in parallel with the first central electrode between the input port and the output port.

8. The non-reciprocal circuit element according to claim 2, wherein an impedance-adjusting capacitor is connected to ground and to the one end of the first central electrode.

9. A two-port isolator comprising the non-reciprocal circuit element according to claim 2.

10. A lumped-constant isolator comprising the non-reciprocal circuit element according to claim 2.
